(19) United States
(12) Patent Application Publication
(10) Pub. No.: US 2016/0021797 A1
(43) Pub. Date: Jan. 21, 2016

(54) BOX SECTION HOUSING MOTOR VEHICLE POWER EQUIPMENT FORMING ELECTROMAGNETIC SCREENING

(71) Applicant: Gérald ANDRE, Amberieu En Bugey (FR)

(72) Inventor: Gerald Andre, Amberieu En Bugey (FR)

(73) Assignee: COMPAGNIE PLASTIC OMNIUM, Lyon (FR)

(21) Appl. No.: 14/774,780

(22) PCT Filed: Mar. 12, 2014
(86) PCT No.: PCT/FR2014/050550

§ 371 Date: Sep. 11, 2015

(30) Foreign Application Priority Data
Mar. 12, 2013 (FR) 1352200

(51) Int. Cl. H05K 9/00; B60R 16/03

(52) U.S. Cl. CPC H05K 9/0007; B60R 16/03; H05K 9/0081

(57) ABSTRACT

A box section housing motor vehicle drive electric power transmission and/or storage onboard equipment, comprising a conductive base layer extending over the entirety of a surface described by the box section, the box section comprising an additional conducting layer made up of at least one conducting material and at least partially covering the conducting base layer.

This invention relates to the housing of electric or hybrid motor vehicle drive batteries and/or electrical components of electric or hybrid motor vehicles transmitting drive electric power of such vehicles.

To encapsulate a battery pack in an electric or hybrid vehicle, the current solution is to provide a fully metal box, made in particular of aluminium, to prevent the batteries from emitting electromagnetic radiation outside the box to passengers or to the vehicle electronics. The choice of this metal is justified by its mechanical strength and conductivity. Electromagnetic screening is in fact required around the housing space to confine the strong fields generated by the batteries and/or the other power electrical components related to the vehicle drive. The high conductivity of aluminium makes it perfectly suitable for this type of electromagnetic screening.

Nevertheless such a solution remains unsatisfactory in terms of compromise between manufacturing cost and screening efficiency. The large quantity of aluminium used to manufacture these boxes makes them heavy and particularly expensive. These boxes are also complex to produce in an industrial mass production process. In addition, such a box is not highly effective in stopping the electromagnetic radiation due specifically to the batteries and the power electrical components accompanying the batteries to convey the vehicle drive power.

The objective of the invention to propose a motor vehicle box to house batteries and/or electrical components transmitting the vehicle drive power, the box being robust, light, sufficiently inexpensive for mass production and offering sufficient screening efficiency to prevent the batteries and/or the electrical components from emitting electromagnetic radiation outside the box to the passengers or to the vehicle electronics.

This objective is achieved according to the invention through a box housing motor vehicle drive electric power transmission and/or storage on-board equipment, the box describing a surface completely enclosing a housing for receiving such equipment, the box comprising a conducting base layer made of at least one conducting material, the box being characterised in that the conducting base layer extends entirely over said surface described by the box and the box comprises an additional conducting layer made of at least one conducting material and at least partially covering said conducting base layer.

Advantageously, the box comprises a layer of electrically insulating material interposed between the conducting base layer and the additional conducting layer.

Advantageously, the conducting base layer is made of at least one electromagnetic screening material.

Advantageously, the conducting base layer is made of at least one material having a conductivity greater than 1.10⁷ S/m.

Advantageously, the conducting base layer comprises at least one part made of aluminium.

Advantageously, the additional conducting layer is made of an electromagnetic type screening material.

Advantageously, said electromagnetic type screening material forming the additional conducting layer has a conductivity greater than 1·10⁷ S/m.

Advantageously, the additional conducting layer is made of a magnetic type screening material.

Advantageously, the magnetic type screening material has a relative magnetic permeability greater than 100.

Advantageously, the magnetic type screening material is part of the group consisting of nickel, iron, permalloy, steel and mu-metals.

Advantageously, the magnetic type screening material is part of the group consisting of iron and steel.

Advantageously, the conducting base layer and the additional conducting layer are made of different materials.

Advantageously, the conducting base layer has a thickness between 0.05 mm and 0.5 mm.

Advantageously, the additional conducting layer has a thickness between 0.05 mm and 0.1 mm.

Advantageously, the box comprises a shell of plastic material or plastic matrix composite material, the conducting base layer and the additional conducting layer at least partially covering said shell.

Advantageously, the shell having an inner side and an outer side with reference to a general shape of the box, the conducting base layer and the additional conducting layer are arranged on the same side of the shell amongst these two sides.

Advantageously, the shell having an inner side and an outer side with reference to a general shape of the box, the conducting base layer (30) and the additional conducting layer are each arranged on a different side of the shell amongst these two sides.

Advantageously, at least one of the layers amongst the conducting base layer (30) and the additional conducting layer is made by providing a sheet of its component material(s) and placing this sheet over said shell (10, 100).

Advantageously, at least one of the layers amongst the conducting base layer (30) and the additional conducting layer is made by spraying its component material(s).

The invention also relates to use as a box housing motor vehicle drive electric power transmission and/or storage on-board equipment of a box describing a surface completely enclosing a housing for receiving equipment, the box comprising a conducting base layer made of at least one conducting material, the conducting base layer extending entirely over the surface described by the box and the box comprising an additional conducting layer made of at least one conducting material and at least partially covering said conducting base layer.

The plastic may be thermoplastic or thermosetting.

It will be easier to understand the invention on reading the description below, given as an example and referring to the drawings, on which:

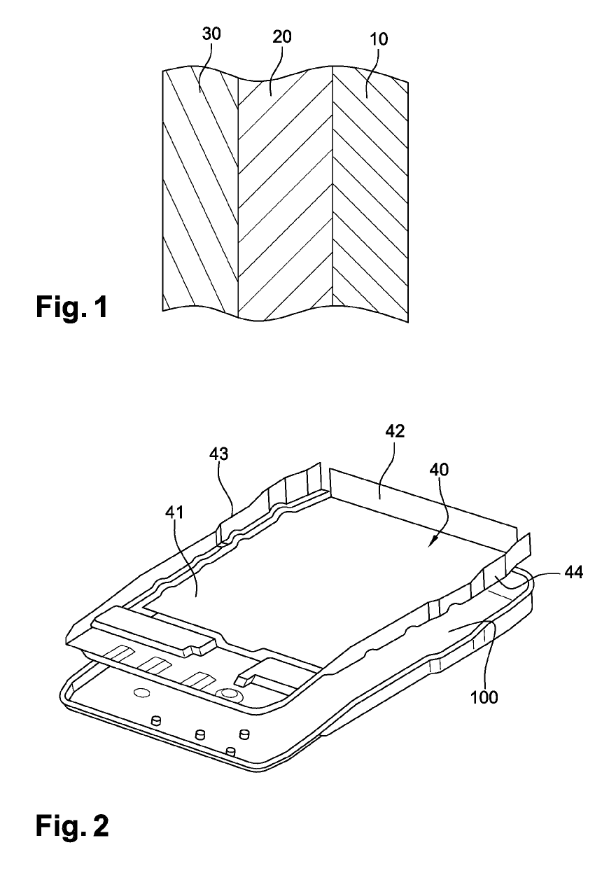

FIG. 1 is a transverse cross-section of a box wall according to one embodiment of the invention;

FIG. 2 is an exploded perspective view of a box according to the same embodiment of the invention.

As shown on FIG. 1, a box now described has a three-layer wall. A first layer 10 is a plastic or organic support layer such as a polymer moulded as a half-shell. The type of plastic used is for example thermoplastic or thermosetting. The support layer may alternatively be a layer of composite material whose matrix is plastic, this plastic being either thermoplastic or thermosetting. In this example, a second layer 20 is a conducting layer having magnetic screening properties, in this case an iron layer. A third layer 30 referred to hereinafter as the conducting base layer is, in this case, an electromagnetic screening layer, in this case an aluminium layer.

This box surrounds a vehicle power equipment receiving space describing a surface which completely encloses such an equipment receiving space. The conducting base layer 30 extends entirely over such a surface so as to leave no free passage for waves emitted by the power equipment to leave the box.

The electromagnetic screening is known per se. It generally uses a highly conducting metal layer, such as an aluminium or copper layer. The conducting properties of the copper or aluminium layer cancel the electrical component of the electromagnetic field, thereby preventing it from crossing the screening formed.

More specifically, preference is given here to an electromagnetic screening material of high conductivity, typically greater than 1·10⁷ S/m. Apart from aluminium or copper, such electromagnetic screening materials include zinc for example. Thus, aluminium has a conductivity of 3.5·10⁷S/m, copper has a conductivity 5.96·10⁷ S/m, zinc has a conductivity of 16.9·10⁶ S/m. These metals are given here by way of example and depending on alternative embodiments, alloys of these various metals or composite materials comprising a matrix, for example made of plastic in which particles of such materials are embedded for their ability to form an electromagnetic barrier, are adopted.

In this example, a magnetic screening material is used for the layer 20, also called the additional conducting layer in the remainder of the document. The efficiency of the magnetic screening depends on the magnetic permeability of the material, or its relative magnetic permeability which is the ratio of the magnetic permeability of the material considered over the magnetic permeability in a vacuum. This efficiency disappears for strong magnetic fields since the material saturates.

In this example, the magnetic screening material forming the layer 20 consists mainly of iron, iron having a relative magnetic permeability of 5000. In this case, the layer 20 is a layer of common steel which has a relative magnetic permeability of 100. Alternatively, the layer 20 is made of nickel. Nickel has a relative magnetic permeability of between 100 and 600 depending on the characteristics of the magnetic field encountered.

Alternatively, a mu-material or mu-metal, also written p-metal is used. A mu-metal is an alloy of nickel and iron. Mu-metal, which has an extremely high magnetic permeability, is particularly suitable for this purpose. Several grades of mu-metal are available, depending on the manufacturer. A “French” mu-metal is typically composed of 80% nickel, 15% iron and 5% molybdenum. Its symbolic designation according to the European standard is NiFe15Mo5. A “German” mu-metal is composed of 77% nickel, 15% iron, 5% copper and 3% molybdenum. Its symbolic designation according to the European standard is NiFe15Cu5Mo3. Mu-metals have a relative magnetic permeability of between 20 000 and 50 000. Permalloy, a registered trademark, or Supermalloy, a registered trademark, which are also alloys composed mainly of iron and nickel, may also be used. Permalloy has a relative magnetic permeability of 8000.

These various materials, and more generally materials having a relative magnetic permeability greater than 100, can produce a surprising overall screening effect at low frequency. For even greater efficiency, a material having a relative magnetic permeability greater than 1000 is preferred.

This electromagnetic screening effect is especially high when the conducting base layer 30 is placed on the side of the batteries or the power electric equipment with respect to the magnetic screening layer 20, therefore towards the inside of the box with respect to the magnetic screening layer 20. In this example, the aluminium conducting layer 30 forms a visible layer inside the box. This arrangement also offers the advantage of protecting the magnetic screening layer 20, which is in this case is mainly iron, from the corrosion which could be caused by a certain degree of humidity in the box or by the presence of acids given off from the batteries.

In another embodiment now described, the layer 20 is a layer made of a material having no magnetic screening properties as such. Thus in the example now described, the material forming the layer 20 is aluminium, the conducting base layer 30 being made of zinc in this example.

It appears that superimposing such electrically conducting layers 20 and 30 produces a surprisingly efficient electromagnetic screening effect for the box, far exceeding the theoretical sum of the two effects of each of the layers 20 and 30 considered separately.

Thus, the box can be made by superimposing two electrically conducting layers, thereby obtaining an already surprising electromagnetic screening effect at low cost when the materials used are inexpensive such as aluminium and zinc in this case.

According to various embodiments, such materials may even be conducting without however being materials with electromagnetic screening properties as such. In another variant, the material of one of the layers may be a material having electromagnetic screening properties, and in another variant the two materials may be electromagnetic screening materials. In another variant, a layer of magnetic screening material is placed between two conducting layers, these two layers possibly having electromagnetic screening properties when taken individually. Such a magnetic screening layer may also be placed between two insulating layers and two conducting layers.

According to one embodiment, the conducting base layer 30, although extending entirely over the surface of the box to completely enclose the equipment receiving space may consist of several materials adjacent to one another. Thus, the conducting base layer 30 may be made of a steel sheet for part of the box so as to give the box structural strength in this part, and be completed for a part made in the form of a conducting paint or in the form of a conducting material deposited by spraying. Such an embodiment is suitable when, in the complementary part so produced, the conducting base layer 30 does not have to produce a surface protection mechanical strengthening effect.

In this case, the batteries and their associated equipment emit electromagnetic radiation of frequencies in the range from 100 Hz to 1 MHz. Thus, in the examples described here, a conducting base layer 30 and an additional conducting layer 20 are superimposed, this superimposition significantly improving the efficiency in this range of low frequency electromagnetic fields and for the electromagnetic field amplitudes present. More generally, to encapsulate such vehicle batteries, which emit low-frequency electromagnetic fields, it appears that this type of superimposition produces a surprising electromagnetic blocking effect.

This produces an effect that can be described as a multi-layer effect, further improved when an insulating layer is interposed, this effect appearing to function according to several types of attenuation. A first effect seems to occur at a conducting layer considered. Some of the electromagnetic radiation is transmitted to the next outer layer while some of the radiation is reflected, returning inside the box. Between two conducting layers, the waves are trapped and bounce, especially if the two conducting layers are separated by an insulating layer. The trapped waves, as well as the waves emitted or reflected, also undergo self-damping caused by a type of phase shift generated when the waves cross through or bounce at the interfaces.

The surprising effect due to the superimposition of such conducting layers 20 and 30 is further increased when these layers are separated by a non-conducting interposed layer. Thus, according to an advantageous embodiment, the conducting base layer 30 and the additional conducting layer 20 are placed on opposite side of the layer 10 forming the plastic shell, the plastic shell then forming the interposition material or gap. Although the thicknesses shown on FIG. 1 are not representative of the true thicknesses, such a shell shown here has a thickness of 3 mm which is particularly suitable in terms of increasing the efficiency due to the interposition layer. More generally, the intermediate insulating layer advantageously has a thickness of between 0.1 mm and 4.0 mm. In such an embodiment, when a layer is made of iron it is advantageously covered with a coat of varnish to protect it from scratches and corrosion or chemical attacks such as redox reactions.

Alternatively, the layers 20 and 30 are placed on the same side of the plastic shell, the layers 20 and 30 being separated by an insulating material made ideally of plastic, whether a thermoplastic material or a thermosetting material. The thickness of such a layer is advantageously less than 2 mm, ideally less than 0.1 mm. Such an insulating layer is for example a varnish such as a thermosetting varnish or an insulating film. Such an embodiment offers the advantage of being more easily implemented industrially. In one embodiment, the fact of depositing an aluminium layer to protect an iron layer protects the iron layer against corrosion more efficiently than a layer of varnish alone. However, a layer of varnish is advantageously deposited on the visible metal layers, whether the metal layer faces towards the inside or the outside of the box, to protect this layer from possible scratches and also against corrosion.

When the layers 20 and 30 are arranged on the inside of the box, there is a risk of electrical contact between the conducting layers and the power systems placed in the box, in case of vehicle accident for example. However, the layers 20 and 30 are better protected on this side of the plastic wall since they are not subject to mechanical aggressions during assembly of the power systems or during maintenance of these systems. In addition, the layers 20 and 30 are protected against environmental aggressions such as humidity which generates corrosion. It must be pointed out that the screening effects produced by these materials may be impaired due to corrosion.

When the layers 20 and 30 are arranged on the outside of the box, there is less risk of electrical contact with the systems inside in case of vehicle collision. However, if at least one layer is arranged on the outside, an insulating layer or a varnish may be required to protect the last metal layer from corrosion or scratches.

For optimum efficiency, the thicknesses of the layers 20 and 30 are given below. Advantageously, the layer 20 has a thickness of between 0.05 mm and 0.1 mm. Advantageously, the conducting base layer 30 has a thickness of between 0.01 mm and 0.2 mm, preferably between 0.05 mm and 0.2 mm for an optimum overall screening effect and cost of the final box. When the layer 20 is a layer of mu-material, its thickness can be reduced to 0.01 mm for example.

The conducting layers 20 and 30 are in this case supplied as sheets on rolls. The sheets are unrolled, then laminated together. Advantageously, a layer of varnish is arranged between the two layers before lamination, this layer of varnish and more generally the insulating layer also bonding the layers 20 and 30 together.

As shown on FIG. 2, the laminated assembly is then shaped by folding and drawing and stamping into a shape of half-shell 40 similar to a half-shell 100 made of plastic material such as a polymer in this case. The assembly 40 formed from these two layers 20 and 30 thus shaped has in this case a substantially flat central portion 41, with a fold 42 at its end and two wings 43 and 44 at its sides. These two wings 43 and 44 extend in this case from one end of the assembly 40 which is opposite to the end with the fold 42, the two wings 43 and 44 extending from this opposite end up to the fold 41. This assembly 40 is then placed inside the half-shell 100, being bonded against the inner face of the half-shell 100, the half-shell then being entirely covered on the inside. An opposite half-shell is equipped in the same way with an assembly consisting of two layers 20 and 30 also laminated together. The half-shells are then assembled together to form the box. Such a box, apart from its efficiency in terms of electromagnetic screening, offers lightness as well as mechanical strength, heat insulating capacity and tightness which make it suitable for receiving batteries or power electrical equipment in a vehicle. The box described here is better adapted to adopt shapes specific to its environment in a reduced space available in the vehicle and more adapted to include, for example by moulding, features such as body attachment interfaces. Alternatively, the assembly 40 once shaped can be overmoulded by a plastic material to form the half-shell 100 on the assembly 40 itself. According to an advantageous arrangement, the assembly 40 formed by the layers 20 and 30 can be worked as microstructures facilitating elongations of this assembly 40 when it is being shaped.

Alternatively, the layers 20 and 30 are formed by spraying their constituent material. Thus, alternatively the layer 20 is produced by spraying powdered iron on the half-shell 100 using the “Arc-spray” method or by spraying molten metal directly onto a half-shell made of composite material, possibly coated with a varnish. The layer 30 may also be sprayed onto the layer 20 using the same method, or be sprayed in the form of molten aluminium, for example. Producing an aluminium layer by spraying powder or molten aluminium offers the advantage of obtaining an aluminium layer 30 which has a certain surface roughness, this roughness producing a beneficial effect of deviating the electromagnetic field lines. The electromagnetic screening effect produced by the assembly of the two layers 20 and 30 is therefore further increased.

A box made according to the examples described herein not only prevents radiation from leaving the box but also prevents exterior radiation from disturbing the equipment housed in the box.

1. A box housing motor vehicle drive electric power transmission and/or storage on-board equipment, said box describing a surface completely enclosing a housing for receiving such equipment, said box comprising a conducting base layer made of at least one conducting material, wherein said conducting base layer extends entirely over said surface described by said box and said box comprises an additional conducting layer made of at least one conducting material and at least partially covering said conducting base layer.

2. The box according to claim 1, wherein said box comprises a layer of electrically insulating material interposed between said conducting base layer and said additional conducting layer.

3. The box according to claim 1, wherein said conducting base layer is made of at least one electromagnetic screening material.

4. The box according to claim 1, wherein said conducting base layer made of at least one material having a conductivity greater than 1·10⁷ S/m.

5. The box according to claim 1, wherein said conducting base layer comprises at least one part made of aluminum.

6. The box according to claim 1, wherein said additional conducting layer is made of an electromagnetic type screening material.

7. The box according to claim 6, wherein said electromagnetic type screening material forming said additional conducting layer has a conductivity greater than 1·10⁷ S/m.

8. The box according to claim 1, wherein said additional conducting layer is made of a magnetic type screening material.

9. The box according to claim 8, wherein said magnetic type screening material has a relative magnetic permeability greater than 100.

10. The box according to claim 9, wherein said magnetic type screening material has a relative magnetic permeability greater than 1000.

11. The box according to claim 8, wherein said magnetic type screening material is part of a group consisting of nickel, iron, permalloy, steel and mu-metals.

12. The box according to claim 8, wherein said magnetic type screening material is part of a group consisting of iron and steel.

13. The box according to claim 1, wherein said conducting base layer and said additional conducting layer are made of different materials.

14. The box according to claim 1, wherein said conducting base layer has a thickness between 0.05 mm and 0.5 mm.

15. The box according to claim 1, wherein said additional conducting layer has a thickness between 0.05 mm and 0.1 mm.

16. The box according to claim 1, wherein said box comprises a shell of plastic material or plastic matrix composite material, said base layer and said additional conducting layer at least partially covering said shell.

17. The box according to claim 16, wherein said shell having an inner side and an outer side with reference to a general shape of said box, said conducting base layer and said additional conducting layer are arranged on the same side of said shell amongst these two sides.

18. The box according to claim 16, wherein said shell having an inner side and an outer side with reference to a general shape of said box, said conducting base layer and said additional conducting layer are each arranged on a different side of said shell amongst these two sides.

19. The box according to claim 16, wherein at least one of the layers amongst said conducting base layer and said additional conducting layer is made by providing a sheet of its component material(s) and placing said sheet over said shell.

20. The box according to claim 1, wherein at least one of the layers amongst said conducting base layer and said additional conducting layer is made by spraying its component material(s).

21. A box housing motor vehicle drive electric power transmission and/or storage on-board equipment, said box for use on a motor vehicle. said box describing a surface completely enclosing a housing for receiving equipment, said box comprising a conducting base layer made of at least one conducting material, said conducting base layer extending entirely over said surface described by said box and said box comprising an additional conducting layer made of at least one conducting material and at least partially covering said conducting base layer.
